(19) United States
(12) Patent Application Publication
(10) Pub. No.: US 2009/0141763 A1
(43) Pub. Date: Jun. 4, 2009

(54) SEMICONDUCTOR LASER

(76) Inventors: Katsumi Kishino, Tokyo (JP); Ichiro Nomura, Tokyo (JP); Tsunenori Asatsuma, Kanagawa (JP); Sumiko Fujisaki, Hachioji (JP); Hitoshi Nakamura, Hachioji (JP); Takeshi Kikawa, Kodaira (JP); Shigehisa Tanaka, Koganei (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/038,055

(22) Filed: Feb. 27, 2008

(30) Foreign Application Priority Data
May 8, 2007 (JP) 2007-123762

(51) Int. Cl. H01S 5/20

(52) U.S. Cl. 372/45.01

(57) ABSTRACT

There is disclosed a Be-containing II-VI group semiconductor laser that has a laminated structure formed on an InP substrate to continuously emit at room temperature without crystal degradation. A basic structure of the semiconductor laser is formed over the InP substrate by use of a lattice-matched II-VI group semiconductor including Be. An active layer and cladding layers are formed to be a double heterostructure with a type I band lineup, in order to increase the efficiency for injecting carriers into the active layer. The active layer and the cladding layers are also formed to enhance the light confinement to the active layer, in which the Mg composition of the p-type cladding layer is set to Mg<0.2.

### CLAIM OF PRIORITY

The present application claims priority from Japanese application serial No. 2007-123762, filed on May 8, 2007, the content of which is hereby incorporated by reference into this application.

### BACKGROUND OF THE INVENTION

1. Field of the Invention

The present invention relates to a semiconductor laser. More particularly, the invention relates to a semiconductor light emitting device, such as a green light emitting laser, using a compound semiconductor of II and VI group elements formed on an InP substrate, and having good carrier and light confinement functions while preventing dedeterioration of the component material.

2. Description of the Related Arts

Semiconductor lasers are used as a light source in various fields of industries such as optical disc, communication, and process. For example, a semiconductor laser emitting in the infrared region (0.98 μm, 1.3 μm, 1.55 μm bands) is used for a transmission light source and an optical amplifier for optical transmission. A 780 nm semiconductor laser is used for CD (Compact Disc), and a 650 nm is used for DVD (Digital Versatile Disc). Currently, a device of 405 nm band is being developed as a next generation light source for DVD with an improved recording density. Table 1 shows the emission wavelength bands and materials of optical devices such as semiconductor lasers.

TABLE 1

| | Optical device type | | | |
|---|---|---|---|---|
| | | Semicon- | | |
| | | ductor | | |
| | | device | | |
| | | emitting in | | |
| | Blue light | yellow- | Red light | Infrared |
| | device | green | device | device |
| Emission | 400 nm band | 500 nm band | 600 nm band | 780 nm, 808 |
| wave- | (especially | | (especially | nm, 860 nm, |
| length | 400-480 nm) | | 635-670 nm) | 915 nm, or |
| band | | | | 980 nm band |
| Material | III-V group | No compound | III-V group | III-V group |
| | compound | semicon- | compound | compound |
| | semiconductor | ductor | semicon- | semicon- |
| | of | available | ductor | ductor |
| | AlGaInN | for | of | of |
| | | continuous | AlGaInP | AlGa(In)As |
| | | emission | | |

As apparent from Table 1, the semiconductor laser emitting in the yellow-green region at a wavelength of 500 nm band has not been put into practice yet. Although approaches have been made to reduce the wavelength in the AlGaInP system of the red light emitting device as well as to extend the wavelength in the AlGaInN system of the blue light emitting device, the performance does not reach a practical level.

When the semiconductor laser emitting at the wavelength of 500 nm band is put into practice, it is expected to be applied to measuring instruments and display devices due to its high visual sensitivity. The semiconductor laser emitting at the wavelength of 500 nm band is also expected to be applied to displays capable of producing a wide range of colors, in combination with the red and blue semiconductor lasers.

II-VI and III-V group compound semiconductors are useful material systems for the semiconductor laser emitting at the wavelength of 500 nm band relating to the field of the present invention. In 1990s, a study of semiconductor laser device formed using ZnSe system material on a GaAs substrate was developed and achieved a device life of 400 hours at room temperature (E. Kato, et al., Electronics Letters, vol. 34, No. 3, pp. 282-284 (1998)). However, such a semiconductor laser device offered no further reliability, failing to reach a practical level. It is thought that this is due to the essential feature of the material system that a crystal defect is likely to occur and likely to move.

Recently, studies have been started on a II-VI group compound semiconductor including Be in the II group elements, as a material for a semiconductor laser emitting at the wavelength of 500 nm band (—2,586,349; JP-A No. 2000-500288; JP-A No. 2004-95922; A. Waag, et al., Journal of Crystal Growth, vol. 184/185, pp. 1-10 (1998)). According to K. Kishino, et al., Physica Status Solidi (c), vol. 1, No. 6, pp. 1477-1486 (2004); Hayami, et al., Oyo Butsuri Gakkai Yokosyu, 31p-ZN-6, No. 52(2005 spring); Y. Nakai, et al., Physica Status Solidi (a), vol. 201, No. 12, pp. 2708-2711 (2004); and I. Nomura, et al., Physica Status Solidi (b), vol. 243, No. 4, pp. 924-928 (2006), a device life of 5000 hours was achieved in a light emitting diode (LED) using BeZnSeTe as an active layer at room temperature with an emission wavelength of 575 nm and injection current of 130 A/cm².

The improvement of the device reliability can be caused by the following reasons. One is the ability to form a lattice-matched crystal on an InP substrate. The other is the ability to prevent generation and expansion of crystal defect due to incorporation of Be into the crystal in which covalent bonding is strong enough to increase the bonding of the crystal.

### SUMMARY OF THE INVENTION

Generally N (nitrogen) is used as a p-type impurity for the fabrication of light emitting device by using a II-VI group compound semiconductor as a component material. For example, the use of N as the p-type impurity is described in E. Kato, et al., Electronics Letters, vol. 34, No. 3, pp. 282-284 (1998), and in Y. Nakai, et al., Physica Status Solidi (a), vol. 201, No. 12, pp. 2708-2711 (2004). However, the activation ratio of N is not high in the II-VI group compound semiconductors, and inactivated nitrogen molecules remain in the crystal.

Further, in order to effectively confine carriers into an active layer of the light emitting device, it is desirable that the band gap of a cladding layer is larger than the band gap of the active layer, and that the band lineup is type I. As a method for increasing the band gap while taking into account the lattice-matching with the substrate, Mg is used as the II group element, for example, such as MgSe. According to W. Shinozaki, et at., Japanese Journal of Applied Physics, vol. 38, pp. 2598-2602 (1999), MgSe and ZnSe_{y}Te_{1-y} superlattices are used as a p-type cladding layer. This is because using the superlattice structure allows an effective control of the band gap by changing the ratio of the film thicknesses of the superlattice layers.

However, in the course of investigations made by the present inventors, on a multilayer crystal of a laser structure having a p-type cladding layer including N-doped superlattice layers of MgSe and BeZnₓTe₁₋ₓ, white turbidity occurred in the crystal after keeping in the atmosphere (FIG. 1) Detailed investigations have been made on the phenomenon, and confirmed peeling in the p-type cladding layer by observation of the cross section by scanning electron microscope (SEM). At the same time, an increase of the concentration of oxygen and hydrogen in the p-type cladding layer was found by secondary ion mass spectrometry (SIMS).

From the results of the investigations, the phenomenon can be explained as follows. According to T. Baron, et al., Journal of Crystal Growth, vol. 184/185, pp. 415-418 (1998), Mg and N are easily coupled to form Mg₃N₂ in N-doped ZnₓCd₁₋ₓSe/ZnᵤCdᵥMg₁₋ᵤ₋ᵥSe superlattices, and the formed Mg₃N₂ is a cause of the crystal defect. Similarly in the sample in which the white turbidity was observed by the present inventors, MgSe and inactive nitrogen were coupled to produce a compound of Mg₃N₂. Generally Mg₃N₂ is highly hygroscopic and is transformed according to the reaction formula: Mg₃N₂+6H₂O to 2NH₃+3Mg(OH)₂. The formation of Mg(OH)₂ causes degradation of the crystal, leading to physical disruption of the crystal due to volume expansion. It can be understood that the white turbidity occurred through the process as described above. Further, even if the crystal is not transformed to the state of white turbidity, there may be a problem that the cladding layer has a high resistance.

The present invention aims at solving the problem of crystal degradation caused by the coupling of Mg and N in the crystal when a laser structure having a desired band lineup is formed using a II-VI group compound semiconductor, and providing a laser crystal structure with excellent crystal stability.

The present inventors have found that a semiconductor laser emitting at the wavelength of 500 nm band can be realized by forming a laser structure to satisfy the following three requirements:

(1) A basic structure of a semiconductor laser is formed using a lattice-matched II-VI group semiconductor including Be on an InP substrate.
(2) A laser structure is formed by active layer and cladding layers forming a double heterostructure with a type-I band lineup. More specifically, the conduction band discontinuity and the valence band discontinuity between the active and p-type cladding layers satisfy ΔEc>300 meV, ΔEv>0 meV, respectively, as well as the conduction band discontinuity and the valence band discontinuity between the active and n-type cladding layers satisfy ΔEc>0 meV, ΔEv>100 meV, respectively.
(3) In each of the layers forming the laser structure, the composition ratio of Mg in the II group elements is Mg<0.2.

The three requirements will be described more in detail below. First, the carrier concentration is increased in order to reduce the resistance of the p-type cladding layer. The activation ratio of N, which is the p-type dopant, is increased using Te as a basic element of the VI group. The carrier confinement effect of the active layer is increased by the use of BeₓZn₁₋ₓSe_{y}Te_{1-y} as an active layer for a Te-based p-type cladding layer. In this way, ΔEc>300 meV and ΔEv>0 meV are both satisfied. FIG. 2 shows the relationship between the band gap and the lattice constant of the II-VI group crystal. From the figure, it is apparent that the emission at the wavelength of 500 nm band can be achieved by the use of this active layer that is lattice matched to the InP substrate. When this active layer is used, it is necessary to use Mg and Be as the II group elements to make the band gap larger in the p-type cladding layer. Further, the composition ratio of Mg is set to less than 0.2 to prevent the crystal degradation. More specifically, BeᵤMgᵥZn₁₋ᵤ₋ᵥTe(v<0.2) is used for the p-type cladding layer.

According to the present invention, a green-wavelength semiconductor laser can be realized in which the carriers and light are sufficiently confined and the crystal degradation is prevented.

### BRIEF DESCRIPTION OF THE DRAWINGS

FIG. 1A is a photograph showing deterioration of a MgSe/BeZnTe crystal, and FIG. 1B is an illustration of the photograph;

FIG. 2 is a diagram showing the composition region of an active layer;

FIG. 3 is a diagram showing the Be content (atomic fraction) dependence to the band gap of the active layer;

FIG. 4 is a diagram showing the crystal structure for photoluminescence measurement of the active layer;

FIG. 5 is a diagram showing the result of the photoluminescence measurement of BeZnSeTe;

FIG. 6 is a diagram showing the Mg content (atomic fraction) dependence to the conduction and valence band energy levels of a p-type cladding layer;

FIG. 7 is a diagram showing the crystal structure for evaluation of the deterioration of BeMgZnTe;

FIG. 8 is a diagram showing the Mg content (atomic fraction) dependence to the crystal degradation;

FIG. 9 is a diagram showing the Be content (atomic fraction) dependence to the conduction and valence band energy levels of an n-type cladding layer;

FIGS. 10A, 10B are diagrams respectively showing the crystal structures for measurement of band discontinuities;

FIGS. 11A, 11B are diagrams showing the results of the band discontinuity measurement made by photoelectron spectroscopy using the samples with surface layers of ZnTe and of BeZnSeTe, respectively;

FIGS. 12A, 12B are diagrams showing the sample structures of the n-type cladding layer and the p-type cladding layer, respectively, for carrier concentration measurement;

FIG. 13 is a diagram showing the structure of a ridge-type green semiconductor laser of a first embodiment according to the present invention; and

FIG. 14 is a diagram showing the structure of a ridge-type green semiconductor laser of a third embodiment according to the present invention.

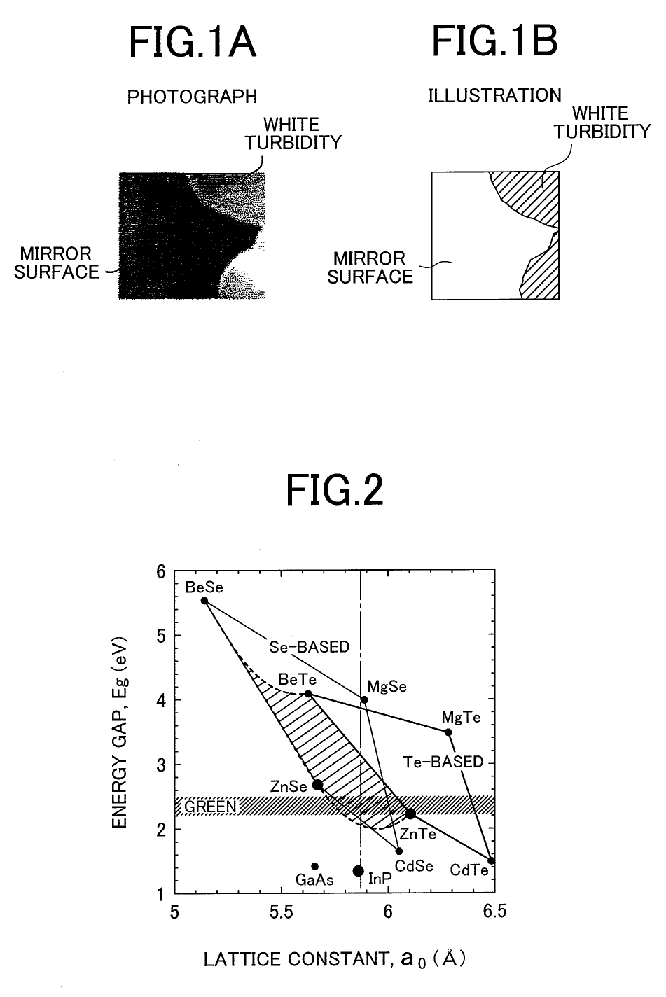

### DETAILED DESCRIPTION OF THE PREFERRED EMBODIMENTS

In the present invention, the material parameters of a multi-element system II-VI group compound semiconductor crystal are calculated using the previously reported material parameters of the two-element system II-VI group compound semiconductor. As a result, Beₓ₁Mg_{y1}Zn_{z1}Te(x1+y1+z1=1) and Beₓ₂Zn₁₋ₓ₂Se_{y2}Te_{1-y2} are determined as the combinations satisfying the above described requirements (1) to (3), for a p-type cladding layer and for an active layer. Next, mixed crystals are formed to satisfy the three requirements, and the material parameters of each of the crystals are measured. The measured material parameters are compared to the calculated values to confirm that the crystals satisfy the three requirements. Next, a semiconductor laser is formed on a trial basis using a combination of the mixed crystals, and then the effect of the present invention is confirmed.

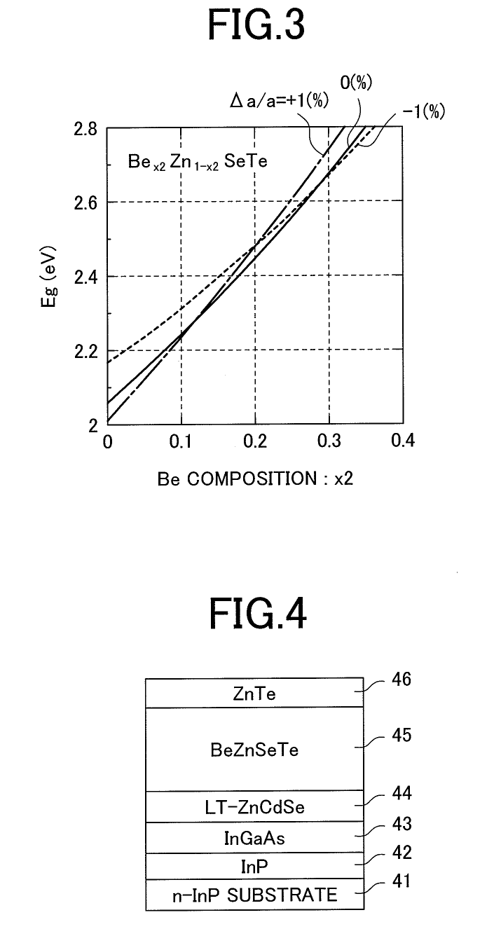

It is possible that the active layer Beₓ₂Zn₁₋ₓ₂Se_{y2} Te_{1-y2} is lattice matched to an InP substrate, and that a band gap Eg is determined in a range of 2.25<Eg<2.5 eV corresponding to the green wavelength band. In the present invention, the allowable range of lattice mismatching is within ±1%, taking into account the formation of a quantum well including Beₓ₂Zn₁₋ₓ₂Se_{y2}Te_{1-y2} as a well layer. This is because the crystal degradation is significant when the lattice mismatching exceeds ±1%. FIG. 3 shows the result obtained by a calculation of the relationship between the band gap (Eg) and the Be composition of Beₓ₂Zn₁₋ₓ₂Se_{y2}Te_{1-y2} in which the lattice mismatching to the InP substrate is within ±1%. Here, the Be composition (x2) is given to provide the lattice matching to the InP substrate, so that one Se composition (y2) is determined. From FIG. 3, it is found that when the Be composition (x2) is in the range of 0.1<2<0.2, the band gap Eg can be determined in the range of 2.25<Eg<2.5 eV with the lattice mismatching of ±1%.

Here, the composition of the active layer will be described with an example of crystal growth by molecular beam epitaxy (MBE) method. The InP substrate with a cleaned surface is placed in an MBE system in which the surface oxide is removed at 500° C. Then, an InP buffer layer is grown to a thickness of 30 nm at a substrate temperature of 450° C., followed by an In_{0.53}Ga_{0.47}As buffer layer to a thickness of 200 nm at 470° C. The compositions are a condition of lattice matching to the InP substrate. Next, a Zn_{0.48}Cd_{0.52}Se buffer layer is grown to a thickness of 5 nm at 200° C. Next, at a substrate temperature of 300° C., a Beₓ₂Zn₁₋ₓ₂Se_{y2}Te_{1-y2} layer is grown to a thickness of 350 nm, and a ZnTe cap layer grown to a thickness of 1 nm. FIG. 4 shows the structure of the crystal formed as described above.

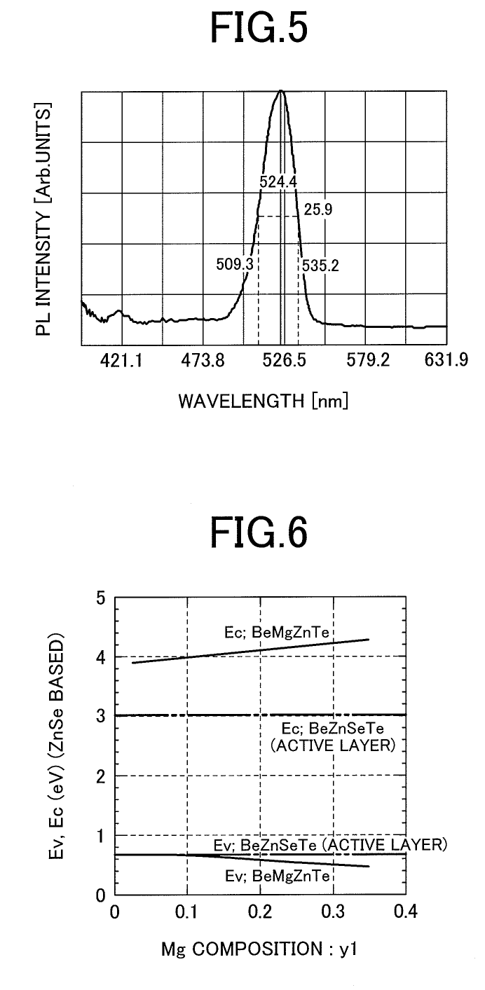

FIG. 5 shows the result of the photoluminescence measurement using the crystal at room temperature. The fourth harmonic (wavelength 266 nm) of an Nd:YAG laser was used for excitation. The peak wavelength is 524.4 nm, which is converted to a band gap of 2.36 eV. The composition of BeZnSeTe was identified as Be_{0.6} Zn_{0.84}Se_{0.36}Te_{0.64}, by the measurements by X-ray diffraction and by photoluminescence (HeCd laser excitation, measured at room temperature) The lattice mismatching is −0.5%. The experimental result agrees well with the calculation shown in FIG. 3.

Next, the conduction band energy Ec and the valence band energy Ev will be described with an example in which Beₓ₁Mg_{y1}Zn_{z1}Te(x1+y1+Z1=1) as the p-type cladding layer is lattice matched to the InP substrate. FIG. 6 shows the relationship, obtained by calculation, between the Mg composition (y1), and Ec and Ev. Here, the values of Ec and Ev are based on ZnSe as the reference value 0. In the figure, there are also shown the values of Ec and Ev when the Be composition (x2) of the active layer Beₓ₂Zn₁₋ₓ₂Se_{y2}Te_{1-y2} is 0.15. From the figure, it is found that when the Mg composition (y1) satisfies y1>0.1, the energy difference ΔEc in the conduction band edge of the active and p-type cladding layers satisfies ΔEc>300 emV, and the energy difference ΔEv in the valence band edge of the active and p-type cladding layers satisfies ΔEv>0 meV. At this time, the Mg composition (y1) of the p-type cladding layer is given to provide the lattice matching to the InP substrate, so that one combination of Be and Zn compositions is determined.

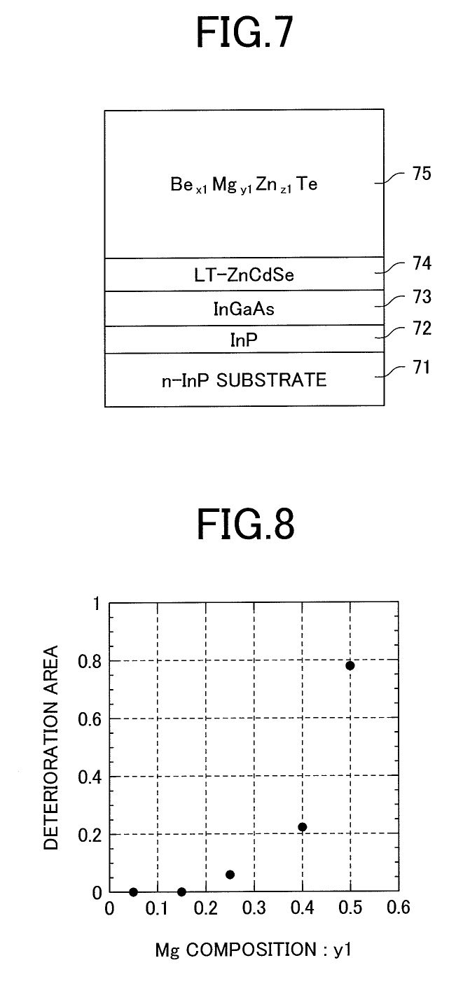

Next, the requirement (3) for the compositions of the p-type cladding layer will be described with an example of crystal growth by the molecular beam epitaxy (MBE) method. The InP substrate with a cleaned surface is placed in the MBE system in which the surface oxide is removed at 500° C. Then, an InP buffer layer is grown to a thickness of 30 nm at a substrate temperature of 450° C., followed by an In_{0.53}Ga_{0.47}As buffer layer to a thickness of 200 nm at 470° C. The compositions are a condition of lattice matching to the InP substrate. Next, a Zn_{0.48}Cd_{0.52}Se buffer layer is grown to a thickness of 5 nm at 200° C. Next, a Beₓ₁Mg_{y1}Zn_{z1}Te (x1+y1+z1=1) is grown at a substrate temperature of 300° C. FIG. 7 shows the structure of the crystal formed as described above. Here, five types of crystals with Mg compositions of 0.05, 0.15, 0.25, 0.4, and 0.5 are formed.

The five types of crystals are kept for a week at a temperature of 50° C. with a humidity of 50%, and the degradation of the crystals is observed by a metallurgical microscope. When the crystal deteriorates, a corresponding part of the crystal surface is no longer a mirror surface. FIG. 8 shows the relationship between the Mg composition and the area ratio of the deteriorated part relative to the surface area of the crystal. No degradation is observed in the crystal for the Mg compositions of 0.05 and 0.15. The deteriorated part is seen for the Mg compositions of 0.25 and 0.4. For the case of the Mg composition of 0.5, most of the crystal surface is occupied by the deteriorated part. Consequently, it is possible to prevent the crystal degradation when the Mg composition of Beₓ₁Mg_{y1}Zn_{z1}Te(x1+y1+z1=1) satisfies Mg<0.2. This Mg composition is suitable for forming a laser from the point of view of the material stability.

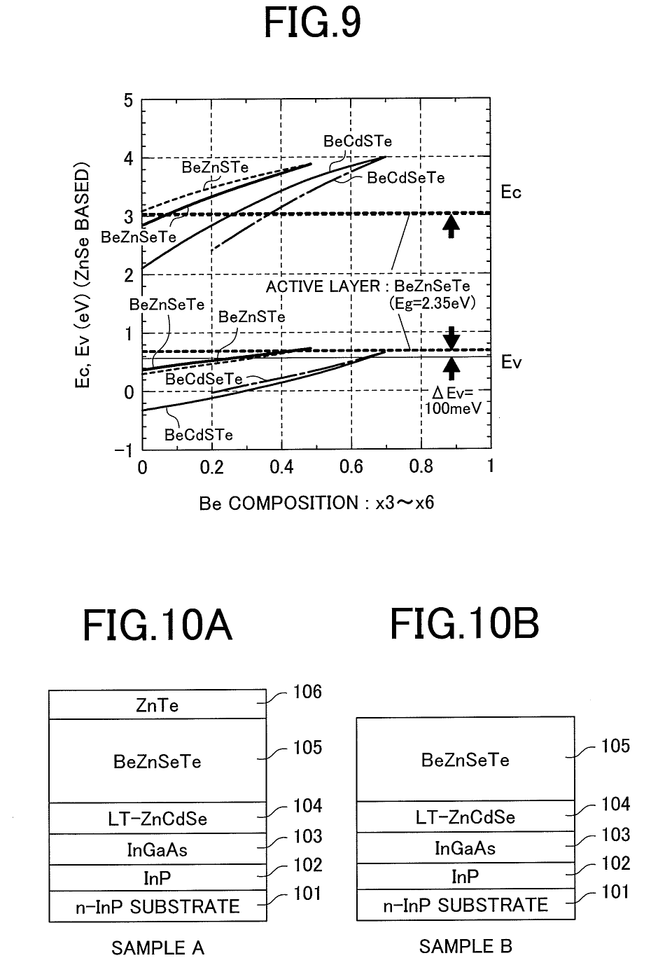

Next, the n-type cladding layer will be described. FIG. 9 shows the result obtained by calculating the relationship of Ec and EV, relative to the Be compositions (x3 to x6) of Beₓ₃Zn₁₋ₓ₃Se_{y3}Te_{1-y3}, Beₓ₄Cd₁₋ₓ₄Se_{y4} Te_{1-y4}, Beₓ₅Zn₁₋ₓ₅S_{y5} Te_{1-y5}, and Beₓ₆Cd₁₋ₓ₆S_{y6}Te_{1-y6}, in the case of lattice matching to the InP substrate. Here, the values of Ec and Ev are based on ZnSe as the reference value 0. In the figure, there are also shown the values of Ec and Ev when the Be composition (x2) of the active layer Beₓ₂Zn₁₋ₓ₂Se_{y2} Te_{1-y2} satisfies 0.1<x2<0. From the figure, it is found that when the Be compositions (x3 to x6) for the n-type cladding layer respectively satisfy 0.05<x3<0.3, 0.45<x4<0.65, 0.15<x5<0.3, and 0.35<x6<0.65, the energy difference ΔEc in the conduction band edge of the active and n-type cladding layers satisfies ΔEc>300 meV, and the energy difference ΔEv in the valence band edge of the active and n-type cladding layers satisfies ΔEv>0 meV. At this time, the Be compositions (x3 to x6) for the n-type cladding layer are given to provide the lattice matching to the InP substrate, so that one combination of element compositions other than the Be composition is determined.

The following is an example of experimental verification on the above described calculations. The first shows an example of the measurement of band discontinuities. Sample A with a surface layer of ZnTe and Sample B with a surface layer of BeZnSeTe are prepared. The InP substrate with a cleaned surface is placed in the MBE system. First, the surface oxide is removed at 500° C. in a III-V dedicated growth chamber. Then, an InP buffer layer is grown to a thickness of 30 nm at a substrate temperature of 450° C., followed by an In_{0.53}Ga_{0.47}As buffer layer grown to a thickness of 200 nm at 470° C. The compositions are a condition of lattice matching to the InP substrate. Next, the sample is delivered to a II-VI dedicated growth chamber in which a Zn_{0.48} Cd_{0.52}Se buffer layer is grown to a thickness of 5 nm at 200° C. Next, at a substrate temperature of 300° C., a BeZnSeTe, which is nearly lattice matched to the InP substrate, is grown to a thickness of 0.5 μm, and a ZnTe is grown to a thickness of 5 nm. The sample is divided into two halves. One is called Sample A. The other sample is subjected to wet etching using Br system etchant to remove the ZnTe layer so that the surface layer is BeZnSeTe. This sample is called Sample B. FIGS. 10A and 10B show the structures of the samples prepared as described above.

The composition of BeZnSeTe was identified as Be_{0.14}Zn_{0.86}Se_{0.38}Te_{0.62}, by the measurements by X-ray diffraction and photoluminescence (HeCd laser excitation, measured at room temperature). Next, using X-ray photoelectron spectroscopy (XPS), Samples A, B are measured to evaluate each of the valence band discontinuities of ZnTe and BeZnSeTe. The measurement is based on the binding energy of the core level of Te which is the common atomic element of the two samples, and measures the energy E_{core/v} from the reference position to the valence band upper edge in each of the samples.

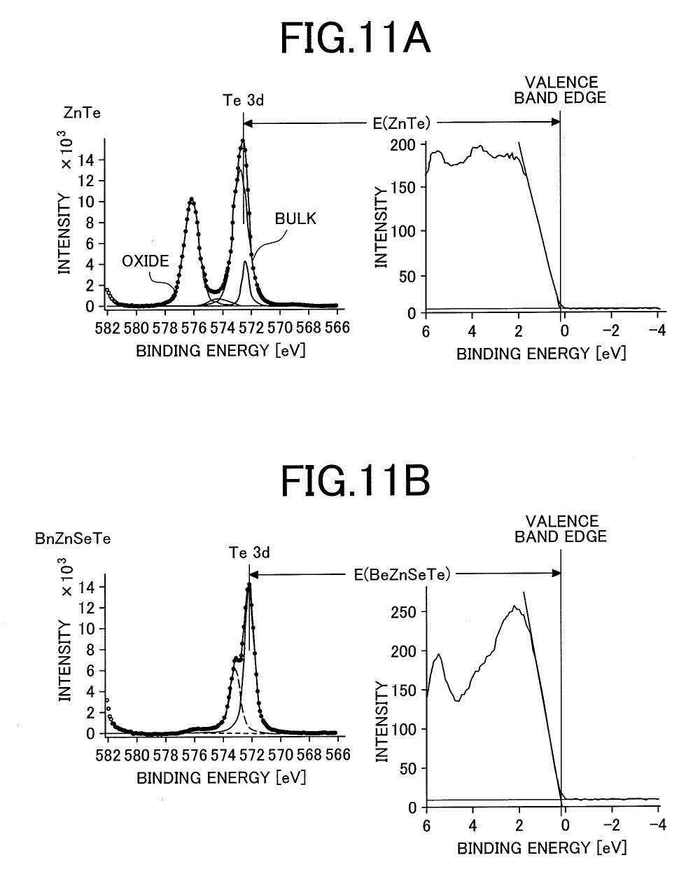

FIGS. 11A, 11B are diagrams showing the results of the band discontinuity measurements of Sample A with the surface layer of ZnTe and Sample B with the surface layer of BeZnSeTe, respectively. The Te-3d orbital signal is shown on the left side of the figure, and the signal from the valence band is shown on the right side. E_{core/v} (ZnTe)=572.32 eV for ZnTe, E_{core/v}(BeZnSeTe)=572.16 eV for BeZnSeTe. As a result, the valence band discontinuity ΔEv, namely, the energy difference ΔEv in the valance band upper edge of the two samples is obtained to be E_{core/v}(ZnTe)−E_{core/v}(BeZnSeTe)=0.16 eV. This value agrees well with ΔEv=0.14 eV which was obtained by calculation. Next, based on this value, the conduction band discontinuity ΔEc of ZnTe/BeZnSeTe is obtained. The ΔEc can be obtained from the following equation: ΔEc=ΔEv+{Eg(ZnTe)−Eg(BeZnSeTe)}, where Eg(ZnTe), Eg(GeZnSeTe) are the band gaps of ZnTe and BeZnSeTe.

Here, the band gap Eg is obtained by the measurements by the photoluminescence and absorption spectrum. As a result, the conduction band discontinuity of ZnTe/BeZnSeTe is obtained to be ΔEc=0.13 eV. It is found that the ZnTe/BeZnSeTe heterojunction is type II.

Table 2 shows an example of the valence band discontinuity ΔEv and conduction band discontinuity ΔEc of the two layers, BeZnSeTe and BeMgZnTe, which were measured by the same method. The calculated values and the experimental values agree well with each other.

Accordingly, it is possible to determine that the above calculated results are sufficiently accurate. Hence, the composition range according to the present invention is effective to improve the characteristics of the II-VI group compound semiconductor laser.

TABLE 2

| | P-type cladding layer | | | | Active layer | | | | Band discontinuity of the p-type cladding | | | |
|---|---|---|---|---|---|---|---|---|---|---|---|---|
| | Material | | | | | | | | layer relative to the active layer | | | |
| | BeMgZnTe | | | | BeZnSeTe | | | | ΔEv (eV) | | ΔEc (eV) | |
| Element | Be | Mg | Zn | Te | Be | Zn | Se | Te | Calc. | Measure | Calc. | Measure |
| Composition | 0.56 | 0.19 | 0.25 | 1.0 | 0.16 | 0.84 | 0.36 | 0.64 | −0.08 | −0.09 | 1.07 | 1.05 |

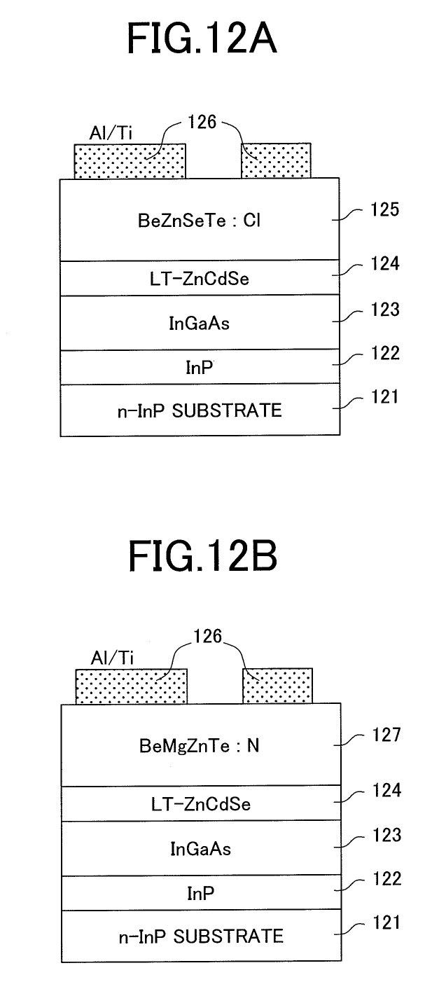

The following is an example of the results of the doping experiment of the material system used for the cladding layer according to the present invention. FIG. 12A shows the prototype structure of a device for measurement of the carrier concentration of an n-type doped BeZnSeTe. ZnCl₂ is used as a dopant and three types of samples having different doping concentrations are prepared. The preparation procedure is shown below. An InP substrate 121 is subjected to an appropriate surface treatment, and then is placed in an MBE system. The InP substrate 121 is put into a preparation chamber for sample exchange, which is vacuumed to below 10⁻³ Pa by a vacuum pump and is heated to 100° C. to remove the residual moisture and impurity gas. Next, the InP substrate 121 is delivered to a III-V dedicated growth chamber in which an oxide film on the substrate surface is removed by heating the substrate to a temperature of 500° C. with irradiation of P molecular beam to the substrate surface. Then, an InP buffer layer 122 is grown to a thickness of 30 nm at a substrate temperature of 450° C., and an InGaAs buffer layer 123 is grown to a thickness of 200 nm at a substrate temperature of 470° C. Next, the sample is delivered to a II-VI dedicated growth chamber in which a ZnCdSe low-temperature buffer layer 124 is grown to a thickness of 5 nm at a substrate temperature of 200° C. after irradiation of Zn molecular beam. Then, a BeZnSeTe layer 125 is laminated to a thickness of 0.5 μm at a substrate temperature of 300° C. ZnCl₂ is used for n-type doping during film growth. The composition obtained by the x-ray diffraction and photoluminescence is Be_{0.2}Zn_{0.8}Se_{0.31}Te_{0.69}.

Next, Ti and Al are evaporated and patterned with resist and light exposure to form two (large and small) Schottky type electrodes 126 as shown in FIG. 12A. Using the electrodes, a capacity-voltage (C-V) measurement is performed at room temperature to obtain an effective donor (n-type doping) concentration in the BeZnSeTe layer 125. The obtained maximum donor concentration is 1.1×10¹⁸ cm⁻³. The result shows that the BeZnSeTe can be applied to the n-type cladding of the semiconductor laser according to the present invention.

Next, FIG. 12B shows the prototype structure of a device for measurement of the carrier concentration of a p-type doped BeMgZnTe. Four types of samples having different doping concentrations are prepared with radial nitrogen doping. The preparation procedure is shown below.

The InP substrate 121 is subjected to an appropriate surface treatment, and then is placed in the MBE system. The InP substrate 121 is put into the preparation chamber for sample exchange, which is vacuumed to below 10⁻³ Pa by a vacuum pump and is heated to 100° C. to remove the residual moisture and impurity gas. Next, the sample is delivered to the III-V dedicated growth chamber in which an oxide film on the substrate surface is removed by heating the substrate to a temperature of 500° C. with irradiation of P molecular beam to the substrate surface. Then, the InP buffer layer 122 is grown to a thickness of 30 nm at a substrate temperature of 450° C., and the InGaAs buffer layer 123 is grown to a thickness of 200 nm at a substrate temperature of 470° C. Next, the sample is delivered to the II-VI dedicated growth chamber in which the ZnCdSe low-temperature buffer layer 124 is grown to a thickness of 5 nm at a substrate temperature of 200° C. after irradiation of Zn molecular beam. Then, the BeZnSeTe layer 125 is laminated to a thickness of 0.5 μm at a substrate temperature of 300° C. The nitrogen radical source is used for the p-type doping. The composition obtained by the x-ray diffraction and photoluminescence is Be_{0.54}Mg_{0.13}Zn_{0.33} Te.

Next, Ti and Al are evaporated and patterned with resist and light exposure to form two (large and small) Schottky type electrodes 126 as shown in FIG. 12B. Using the electrodes, the capacity-voltage (C-V) measurement is performed at room temperature to obtain an effective acceptor (p-type doping) concentration in the BeMgZnTe layer. The obtained maximum acceptor concentration is 7×10¹⁷ cm⁻³. This result shows that the BeMeZnTe can be applied to the p-type cladding of the semiconductor laser according to the present invention.

Hereinafter, preferred embodiments of the semiconductor laser according to the present invention will be described in detail.

### Embodiment 1

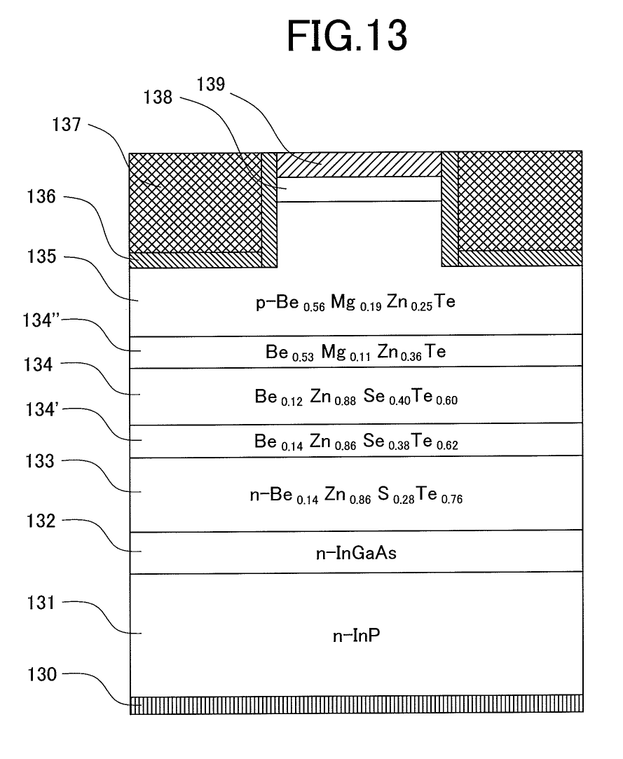

FIG. 13 is a diagram showing the structure of a ridge-type green semiconductor laser of a first embodiment according to the present invention. Reference numeral 131 denotes an n-type InP substrate; 132 denotes an n-type InGaAs buffer layer (film thickness 0.5 μm); 133 denotes an n-type Be_{0.14}Zn_{0.86}S_{0.28}Te_{0.76} cladding layer (film thickness 1 μm); 134 denotes a Be_{0.12}Zn_{0.88}Se_{0.4}Te_{0.6} active layer; 135 denotes a p-type Be_{0.56}Mg_{0.19}Zn_{0.25}Te cladding layer (film thickness 1 μm); and 138 denotes a p-type BeZnTe/ZnTe composition modulated superlattice contact layer. The active layer 134 is sandwiched between a Be_{0.14}Zn_{0.86}Se_{0.38}Te_{0.62} optical guiding layer (film thickness 20 nm) 134′ and a Be_{0.53}Mg_{0.11}Zn_{0.36}Te optical guiding layer (film thickness 20 nm) 134″. Reference numeral 130 denotes an n electrode of a AuGeNi/Pt/Au layer, and reference numeral 139 denotes a p electrode of a Ni/Ti/Pt/Au layer. Reference numeral 136 denotes a SiN protective film, and reference numeral 137 denotes polyimide for planarization of the top surface.

Crystal growth is performed using a two-chamber MBE system having a III-V dedicated chamber and a II-VI dedicated chamber. The growth temperatures of the III-V group (GaInAs) and II-VI group are taken as 500° C. and 280° C., respectively. Zn irradiation is performed to prevent displacement from occurring in the interface between the two groups. ZnCl₂ and RF-nitrogen plasma sources are used as n-type dopant and p-type dopant for the II-VI group. The ridge is formed by wet etching using chromic acid, hydrobromic acid solution. After the formation of the SiN protective film by a plasma CVD method, the polyimide is applied by spin coating. Then, the top surface of the device is planarized by etching back using an O₂ asher. The electrodes 130, 139 are formed via electron beam evaporation. The width of the mesa top surface is taken as 5 μm. The device length of the laser, in which a resonator end face is formed by cleavage, is taken as 800 μm. The device of the first embodiment continuously emits at room temperature. The emission wavelength is 541 nm, and the threshold current is 50 mA. There is no change observed in the surface of the laser crystal of the first embodiment, after keeping the crystal for a week at a temperature of 50° C. with a humidity of 50%.

### Embodiment 2

Similarly three types of devices are prototyped using Be_{0.58}Cd_{0.42}Se_{0.25}Te_{0.75}, Be_{0.2}Zn_{0.8} Se_{0.31}Te_{0.69}, Be_{0.50}Cd_{0.50}S_{0.26}Te_{0.74} instead of the n-cladding layer used in the first embodiment. Their respective threshold currents of 49 mA, 52 mA, and 53 mA are nearly equal to the results described above.

### Embodiment 3

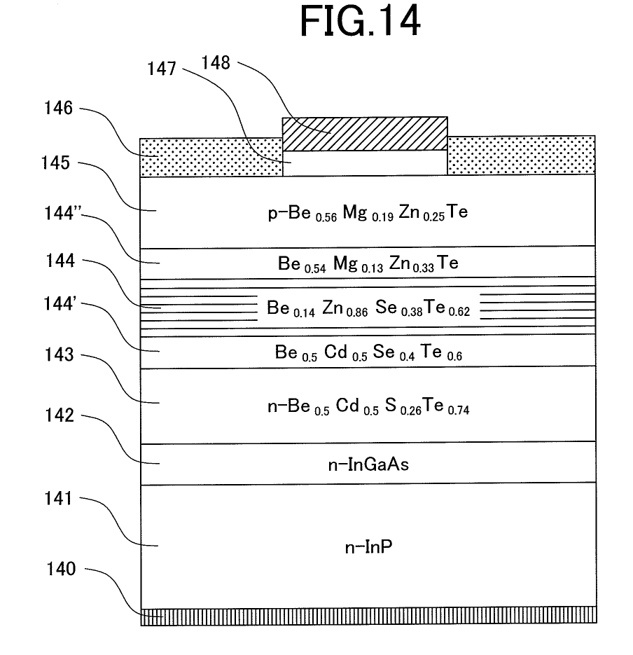

FIG. 14 is a diagram showing the structure of a stripe-geometry green semiconductor laser of a third embodiment according to the present invention. Reference numeral 141 denotes an n-type InP substrate; 142 denotes an n-type InGaAs buffer layer (film thickness 0.5 μm); 143 denotes an n-type Be_{0.5}Cd_{0.5}S_{0.26}Te_{0.74} cladding layer (film thickness 1 μm); 144 denotes a three-cycle multiple quantum well active layer having Be_{0.14}Zn_{0.86}Se_{0.36}Te_{0.62} as a well layer; 145 denotes a p-type Be_{0.56}Mg_{0.19}Zn_{0.25}Te cladding layer (film thickness 1 μm); and 147 denotes a p-type BeZnTe/ZnTe composition modulated superlattice contact layer. The active layer 144 is sandwiched between a Be_{0.5}Cd_{0.5}Se_{0.4}Te_{0.6} optical guiding layer (film thickness 20 nm) 144′, and a Be_{0.54}Mg_{0.13}Zn_{0.33}Te optical guiding layer (film thickness 20 nm) 144″. Reference numeral 140 denotes an n electrode of a AuGeNi/Pt/Au layer, and reference numeral 148 denotes a p electrode of a Ni/Ti/Pt/Au layer. Reference numeral 146 denotes a SiO₂ protective film.

Crystal growth is performed using the two-chamber MBE system having the III-V dedicated chamber and the II-VI dedicated chamber. The growth temperatures of the III-V (GaInAs) and II-VI group are taken as 500° C. and 280° C., respectively. Zn irradiation is performed to prevent displacement from occurring in the interface between the two groups. ZnCl₂ and RF-nitrogen plasma sources are used as n-type dopant and p-type dopant for the II-VI group. The contact layer is etched for current constriction by wet etching using chromic acid, hydrobromic acid solution. After the formation of the SiO₂ protective film by the plasma CVD method, electrode holes are formed on the protective film by dry etching. The electrodes 140, 148 are formed via electron beam evaporation. The width of the mesa top surface is taken as 10 μm. The device length of the laser, in which a resonator end face is formed by cleavage, is taken as 800 μm. The device of the third embodiment continuously emits at room temperature. The emission wavelength is 532 nm, and the threshold current is 90 mA. There is no change observed in the surface of the laser crystal of the third embodiment, after keeping the crystal for a week at a temperature of 50° C. with a humidity of 50%.

### Embodiment 4

Similarly three types of devices are prototyped using Be_{0.58}Cd_{0.42}Se_{0.25}Te_{0.75}, Be_{0.2}Zn_{0.8}S_{0.2}Te_{0.2}, Be_{0.2}Zn_{0.8}Se_{0.31}Te_{0.69}, instead of the n-cladding layer used in the third embodiment. The respective threshold currents of 92 mA, 89 mA, and 90 mA are nearly equal to the results described above.

Because green is more visible than other colors, the semiconductor laser emitting in the green wavelength band, which can be obtained by the present invention, is capable of displaying with high sensitivity at a low light output. Hence, viewability and eye-safety are improved compared to the display system in use with a red laser. Further, it is possible to realize a full-color compact display by combining the green light semiconductor laser with other semiconductor lasers emitting in red and in blue, namely, by combining the three primary colors of light. The display with the semiconductor laser can produce a wide range of colors, and can express colors closer to the real colors than those produced by the conventional CRT (Cathode Ray Tube). In addition, due to its compact size, the semiconductor laser according to the present invention can be applied to displays that have not existed before. For example, very compact projection systems, eyeglass-type displays for wearable PC, projection head-up displays for automobile windshield, and other display devices.

What is claimed is:

1. A semiconductor laser comprising an n-type cladding layer, an active layer, and a p-type cladding layer on an InP substrate,
wherein the active layer has a semiconductor layer formed of a material including Beₓ₂Zn₁₋ₓ₂Se_{y2}Te_{1-y2} (1>x2>0, 1>y2>0) at a composition ratio of 80% to 100%, or a quantum well layer in which a well layer is formed of a material including Beₓ₂Zn₁₋ₓ₂Se_{y2}Te_{1-y2} at a composition ratio of 80% to 100%, and
wherein the p-type cladding layer has a semiconductor layer formed of a material including Beₓ₁Mg_{y1}Zn_{z1}Te (x1+y1+z1=1, x1>0, y1>0, z1>0) at a composition ratio of 80% to 100%.

2. The semiconductor laser according to claim 1,
wherein the n-type cladding layer is formed of a material including any one of Beₓ₃Zn₁₋ₓ₃Se_{y3}Te_{1-y3} (1>x3>0, 1>y3>0), Beₓ₄Cd₁₋ₓ₄Se_{y4}Te_{1-y4} (1>x4>0, 1>y4>0), Beₓ₅Zn₁₋ₓ₅S_{y5}Te_{1-y5} (1>x5>0, 1>y5>0), or Beₓ₆Cd₁₋ₓ₆S_{y6}Te_{1-y6} (1>x6>0, 1>y6>0), at a composition ratio of 80% to 100%.

3. The semiconductor laser according to claim 1,
wherein the energy difference in the valence band edge of the active layer and the n-type cladding layer is not less than 100 meV but not more than 2 eV.

4. The semiconductor laser according to claim 1,
wherein the energy difference in the conduction band edge of the active layer and the p-type cladding layer is not less than 300 meV but not more than 1 eV.

5. The semiconductor laser according to claim 1,
wherein the energy difference in the valence band edge of the active layer and the n-type cladding layer, is not less than 100 meV but not more than 2 eV, and
wherein the energy difference in the conduction band edge of the active layer and the p-type cladding layer is not less than 300 meV but not more than 1 eV.

6. The semiconductor laser according to claim 2,
wherein the energy difference in the valence band edge of the active layer and the n-type cladding layer is not less than 100 meV but not more than 2 eV, and
wherein the energy difference in the conduction band edge of the active layer and the p-type cladding layer is not less than 300 meV but not more than 1 eV.

7. A semiconductor laser comprising an n-type cladding layer, an active layer, and a p-type cladding layer on an InP substrate,
wherein the active layer has a semiconductor layer formed of a material including Beₓ₂Zn₁₋ₓ₂Se_{y2}Te_{1-y2} (1>x2>0, 1>y2>0) at a composition ratio of 80% to 100%, or a quantum well layer in which a well layer is formed of a material including Beₓ₂Zn₁₋ₓ₂Se_{y2}Te_{1-y2} at a composition ratio of 80% to 100%, and
wherein the p-type cladding layer is lattice matched to the InP substrate with a lattice mismatch within ±1%, including Beₓ₁Mg_{y1}Zn_{z1}Te (x1+y1+z1=1, x1>0, y1>0, z1>0) at a composition ratio of 80% to 100% in which the Mg composition y1 satisfies y1<0.35.

8. The semiconductor laser according to claim 7,
wherein the n-type cladding layer is formed of a material including any one of Beₓ₃Zn₁₋ₓ₃Se_{y3}Te_{1-y3} (1>x3>0, 1>y3>0), Beₓ₄Cd₁₋ₓ₄Se_{y4}Te_{1-y4} (1>x4>0, 1>y4>0), Beₓ₅Zn₁₋ₓ₅S_{y5}Te_{1-y5} (1>x5>0, 1>y5>0), or Beₓ₆Cd₁₋ₓ₆S_{y6}Te_{1-y6} (1>x6>0, 1>y6>0), at a composition ratio of 80% to 100%.

9. The semiconductor laser according to claim 7,
wherein the n-type cladding layer is formed of a material including Beₓ₃Zn₁₋ₓ₃Se_{y3}Te_{1-y3} (1>x3>0, 1>y3>0) at a composition ratio of 80% to 100% in which the Be composition x3 satisfies 0.1<x3<0.3.

10. The semiconductor laser according to claim 7,
wherein the n-type cladding layer is formed of a material including Beₓ₄Cd₁₋ₓ₄Se_{y4}Te_{1-y4} (1>x4>0, 1>y4>0) at a composition ratio of 80% to 100% in which the Be composition x4 satisfies 0.4<x4<0.65.

11. The semiconductor laser according to claim 7,
wherein the n-type cladding layer is formed of a material including Beₓ₅Zn₁₋ₓ₅S_{y5}Te_{1-y5} (1>x5>0, 1>y5>0) at a composition ratio of 80% to 100% in which the Be composition x5 satisfies 0<x5<0.3.

12. The semiconductor laser according to claim 7
wherein the n-type cladding layer is formed of a material including Beₓ₆Cd₁₋ₓ₆S_{y6}Te_{1-y6} (1>x6>0, 1>y6>0) at a composition ratio of 80% to 100% in which the Be composition x6 satisfies 0.25<x6<0.65.

13. A semiconductor laser comprising an n-type cladding layer, an active layer, and a p-type cladding layer on an InP substrate,
wherein the active layer and the p-type cladding layer are lattice matched to the InP substrate with a lattice mismatch within ±1%,
wherein the active layer has a semiconductor layer formed of a material including Beₓ₂Zn₁₋ₓ₂Se_{y2}Te_{1-y2} (0.2>x2>0.1, 1>y2>0) at a composition ratio of 80% to 100%, or a quantum well layer in which a well layer is formed of a material including Beₓ₂Zn₁₋ₓ₂Se_{y2}Te_{1-y2} (0.2>x2>0.1, 1>y2>0) at a composition ratio of 80% to 100%, and
wherein the p-type cladding layer is formed of a material including Beₓ₁Mg_{y1}Zn_{z1}Te (x1+y1+z1=1, x1>0, 0.35>y1>0, z1>0) at a composition ratio of 80% to 100%.

14. The semiconductor laser according to claim 13,
wherein the Mg composition y1 of Beₓ₁Mg_{y1}Zn_{z1}Te (x1+y1+z1=1, x1>0, 0.35>y1>0, z1>0) forming the p-type cladding layer satisfies y1<0.2.

15. The semiconductor laser according to claim 13,
wherein the n-type cladding layer is formed of a material including any one of Beₓ₃Zn₁₋ₓ₃Se_{y3}Te_{1-y3} (1>x3>0, 1>y3>0), Beₓ₄Cd₁₋ₓ₄Se_{y4}Te_{1-y4} (1>x4>0, 1>y4>0), Beₓ₅Zn₁₋ₓ₅S_{y5}Te_{1-y5} (1>x5>0, 1>y5>0), or Beₓ₆Cd₁₋ₓ₆S_{y6}Te_{1-y6} (1>x6>0, 1>y6>0), at a composition ratio of 80% to 100%.

16. The semiconductor laser according to claim 13,
wherein the n-type cladding layer is formed of a material including Beₓ₃Zn₁₋ₓ₃Se_{y3}Te_{1-y3} (1>x3>0, 1>y3>0) at a composition ratio of 80% to 100% in which the Be composition x3 satisfies 0.1<x3<0.3.

17. The semiconductor laser according to claim 13,
wherein the n-type cladding layer is formed of a material including Beₓ₄Cd₁₋ₓ₄Se_{y4}Te_{1-y4} (1>x4>0, 1>y4>0) at a composition ratio of 80% to 100% in which the Be composition x4 satisfies 0.4<x4<0.65.

18. The semiconductor laser according to claim 13,
wherein the n-type cladding layer is formed of a material including Beₓ₅Zn₁₋ₓ₅S_{y5}Te_{1-y5} (1>x5>0, 1>y5>0) at a composition ratio of 80% to 100% in which the Be composition x5 satisfies 0<x5<0.3.

19. The semiconductor laser according to claim 13, wherein the n-type cladding layer is formed of a material including Beₓ₆Cd₁₋ₓ₆S_{y6}Te_{1-y6} (1>x6>0, 1>y6>0) at a composition ratio of 80% to 100% in which the Be composition satisfies 0.25<x6<0.65.
